(19) United States
(12) Patent Application Publication
(10) Pub. No.: US 2018/0321292 A1
(43) Pub. Date: Nov. 8, 2018

(54) PORTABLE ANECHOIC CHAMBER

(71) Applicant: Rohde & Schwarz GmbH & Co. KG, München (DE)

(72) Inventors: Hendrik Bartko, Unterhaching (DE); Iratxe Fernandez Anton, München (DE); Erwin Boehler, München (DE); Alexander Pabst, Taufkirchen (DE); Christian F. Fischer, München (DE); Markus Herbrig, Grafing (DE)

(21) Appl. No.: 15/587,495

(22) Filed: May 5, 2017

(51) Int. Cl. G01R 29/08; G01R 29/10

(52) U.S. Cl. CPC G01R 29/0821; H04B 17/101; G01R 29/105

(57) ABSTRACT

A portable anechoic chamber for testing a device under test, comprises a number of test antennas, each test antenna having at least one polarization, an antenna positioning means for positioning at least one of the test antennas in elevation direction relative to the device under test, and a device positioning means for positioning the device under test in azimuth direction.

### TECHNICAL FIELD

The present invention relates to a portable anechoic chamber.

### BACKGROUND

Although applicable in principal to any measurement system, the present invention and its underlying problem will be hereinafter described in combination with anechoic test chambers.

Modern communication systems increasingly use wireless communication between the single devices.

During development or production of devices for such communication systems it is therefore necessary to thoroughly test the wireless communication capabilities of the devices for compliance with communication standards and legal regulations.

For testing such devices it is necessary to position the test antennas in a plurality of different positions around the respective device under test.

Against this background, the problem addressed by the present invention is to provide a versatile test equipment for wireless communication devices.

### SUMMARY

The present invention solves this object by a portable anechoic chamber with the features of claim 1.

Accordingly it is provided:
A portable anechoic chamber for testing a device under test, the portable anechoic chamber comprising a number, i.e. one or more, of test antennas, each test antenna having at least one polarization, an antenna positioning means for positioning at least one of the test antennas in elevation direction, i.e. vertically, relative to the device under test, a device positioning means for positioning the device under test in azimuth direction, i.e. rotatably.

The anechoic chamber of the present invention may e.g. be used to test or measure the properties of antennas or antenna arrays or wireless devices with such antennas or antenna arrays.

In the anechoic chamber the DUT or device under test, i.e. the antenna or wireless device, may be positioned on the device positioning means and may be rotatably positioned, i.e. in azimuth direction, in the anechoic chamber.

The test antennas may be distributed inside of the anechoic chamber, especially pointing or focusing on the DUT. Further, at least one of the test antennas may be provided on the antenna positioning means. In case that only one single test antenna is provided in the anechoic chamber this single test antenna will be provided on the antenna positioning means. It is however understood, that the antenna positioning means may also carry more than one of the test antennas and that at the same time further test antennas may be fixed to e.g. an inner side of a housing of the anechoic chamber.

With the antenna positioning means at least one test antenna can therefore be moved in vertical direction with a single actuator and the vertical or elevation distance of the at least one test antenna to the DUT may easily be adjusted. Especially with more than one test antenna on the antenna positioning means a very flexible arrangement is therefore provided that allows easily setting up a test in the anechoic chamber.

The antenna positioning means may e.g. comprise an extendible post, either electric or hydraulic, or any other type of linear motion mechanism that allows lowering and lifting, or extending and retracting, the test antennas in vertical direction. The device positioning means in contrast may e.g. comprise a turning table arrangement or the like. The turning table may e.g. be directly driven by an electric motor or the like or indirectly via a belt or chain or the like.

It is understood, that the antenna positioning means and the device positioning means may be controlled individually and independently.

The anechoic chamber therefore provides a very flexible and easily adjustable test environment for testing antennas, antenna arrays or devices with such antennas.

Further embodiments of the present invention are subject of the further subclaims and of the following description, referring to the drawings.

In a possible embodiment, the antenna positioning means may comprise a linear positioning unit for positioning the at least one test antenna in a direction orthogonal to the elevation movement.

The elevation movement is a vertical movement and therefore allows setting up the distance of the test antennas to the device under test. With the linear positioning unit it is also possible to setup the horizontal distance between the test antennas and the DUT. Required test positions for the test antennas can therefore easily be arranged.

The linear positioning unit may e.g. be coupled to a vertical movement unit of the antenna positioning means. The vertical movement unit may e.g. comprise the above mentioned extendible post or other type of linear motion mechanism. The linear positioning unit may therefore e.g. be lifted and lowered by the vertical movement unit. It is understood, that a reverse arrangement is also possible, where the vertical movement unit is arranged on the linear positioning unit. The linear positioning unit may be coupled to a housing or another support construction of the anechoic chamber.

The linear positioning unit may e.g. comprise guides or rails with a slide attached. The test antennas may be arranged on a support structure that may be attached to the slide. The slide can be moved via an electric motor, hydraulic movement systems or the like.

In a possible embodiment, the linear positioning unit may move the at least one test antenna on an arc-shaped path.

The linear positioning unit may not only move the test antennas on a straight line. Instead, the linear positioning unit may provide for a movement in at least two dimensions, e.g. horizontal and vertical at the same time. The arc-shaped path may e.g. be provided by arc-shaped guides or rails that may be formed such that all points on the arc-shaped path comprise the same distance to the DUT.

In a possible embodiment, the linear positioning unit may rotate the at least one test antenna such that the at least one test antenna points to the device under test on all points of the arc-shaped path.

If the test antennas are rotated such that they always point toward the DUT, the main axis or axis of main sensitivity of the test antennas will always point to the DUT. Therefore homogenous and repeatable measurements will be possible.

In a possible embodiment, the antenna positioning means may comprise a rotational positioning unit for rotating the at least one test antenna in an axis parallel to the elevation movement.

The rotational positioning unit may e.g. comprise a swivel joint or hinge or the like that allows rotating the test antennas. The rotational positioning unit may e.g. be arranged between the vertical movement unit and the linear positioning unit of the antenna positioning means. As an alternative the rotational positioning unit may be provided between the vertical movement unit and the housing or another support construction of the anechoic chamber.

The possibility to rotate the test antennas provides another degree of freedom for freely positioning the test antennas in the anechoic chamber.

In a possible embodiment, the antenna positioning means may comprise for every single test antenna a rotatable joint or hinge for rotating the test antennas about the axis of main sensitivity of the respective test antenna.

The rotatable joint may be manually or electronically operated. Rotating the test antennas about their respective axis of main sensitivity allows adapting the polarization of the test antennas with respect to the device under test.

In a possible embodiment, the antenna positioning means and/or the device positioning means may comprise electric positioning drives for positioning the test antennas and/or the device under test, respectively.

With electric drives positioning the test antennas and/or the device under test, the test arrangement may be externally controller e.g. by a computer. Automation of different test scenarios is therefore easily possible.

In a possible embodiment, the device positioning means may comprise a rotatable support for the device under test for rotating the device under test about a vertical axis.

The rotatable support may e.g. comprise a rotating table or the like that provides fixation means for the device under test to securely fix the device under test to the rotatable support.

In a possible embodiment, the rotatable support may comprise a pivotable joint, also called ball joint or spherical joint, for pivoting the device under test out of the rotating axis.

The pivotable joint allows changing or tilting the main axis or axis of main sensitivity of the device under test in the anechoic chamber.

In a possible embodiment, the antenna positioning means and/or the device positioning means may comprise a gantry arrangement.

The gantry arrangement may e.g. comprise one or two side posts and a middle carrier. The gantry arrangement may however also comprise a single side arm. Such a single side arm gantry arrangement may e.g. comprise a robotic arm or the like with a plurality of joints. Another gantry arrangement may comprise a single arc-shaped post.

A gantry arrangement is a very stable yet flexible mechanical arrangement that allows positioning the test antennas and/or the DUT freely.

In a possible embodiment, the antenna positioning means may comprise signal processing means connected to the test antennas.

The signal processing means may e.g. comprise any signal processing stage that may be necessary to process the signals received by the test antennas. Such signal processing means may e.g. comprise analog-to-digital converters, filters, frequency converters, mixers, amplifier, attenuators, or the like. The signal processing means may e.g. be provided as discrete elements, DSPs, ASICs, FPGAs or any combination of these.

The signal processing means may e.g. output digital data that represents the analog signals of the test antennas. The digital data may then be provided to any other signal processing devices outside of the anechoic chamber. Transporting only the digital signals is more robust than transporting the analog signals from the test antennas to the external signal processing devices. The test results may therefore be more reliable.

In a possible embodiment, the device positioning means may comprise signal processing means connected to the device under test.

The same possibilities as described above for the signal processing means on the antenna positioning means also applies to the signal processing means on the device positioning means.

In a possible embodiment, at least one of the test antennas may comprise an over the air power sensor.

An over the air, OTA, power sensor may serve for measuring power of a wireless signal. The OTA power sensor may sense power in at least two different polarizations and may comprise a power sensor for every polarization, every power sensor comprising a signal detector for detecting the wireless signal. The signal detectors may e.g. be single polarized and the polarization planes of the signal detectors may be arranged at an angle of more than zero degree to each other and the main radiation vectors, i.e. the vectors which represent the main radiation/reception direction, of the signal detectors may be parallel to each other. The power sensors may each comprise a power measurement device, which is configured to measure the power of the detected wireless signal and output a respective measurement signal. The power sensors each detect the wireless signal in one of at least two different polarizations and measure the power levels of the wireless signal in the respective polarization. The power measurement devices may e.g. be provided as diode based power measurement devices. Such OTA power sensors are e.g. disclosed in U.S. patent application Ser. No. 15/468,238, which is incorporated herein by reference.

In a possible embodiment, the portable anechoic chamber may comprise cables connecting the test antennas and/or the device under test, wherein the cables may comprise rotary joints and/or slip rings.

The cables may e.g. be RF cables for transporting measurement signals from the test antennas and/or the device under test. Digital data cables may also be provided. The cables may also be control signal cables for controlling the device under test and/or the test antennas.

With the rotary joints and the slip rings the cables may connect to the test antennas and/or the device under test and at the same time the full range of movement may be provided for the test antennas and the device under test.

In a possible embodiment, the portable anechoic chamber may comprise a chamber housing that at least comprises the antenna positioning means with the test antennas, and the device positioning means, the portable anechoic chamber may further comprise a lower device compartment arranged under the chamber housing and/or an upper device compartment arranged above the chamber housing.

The chamber housing may e.g. comprise an isolated outer case with a door or detachable cover that provides access to the inner chamber for adjusting the test setup in the anechoic chamber.

The lower device compartment arranged below and/or the upper device compartment arranged above the anechoic chamber provide spaces e.g. for installing test equipment or storage space for cables, power supplies or the like.

In a possible embodiment, the portable anechoic chamber may comprise a control unit in the lower device compartment and/or the upper device compartment.

The control unit may e.g. comprise control means for controlling the antenna positioning means and/or the device positioning means. The control unit may also comprise a computer with a screen and a user interface, e.g. a keyboard, a mouse, a trackball or a touchscreen. The computer may e.g. run an operating system and applications that control the test chamber and may serve to evaluate the test results and/or forward the test results e.g. to a central server for further processing and/or storage.

In a possible embodiment, the portable anechoic chamber may comprise a rack with an electric backplane, wherein the chamber housing may be installed in the rack and communicated via the backplane.

The rack may e.g. be a 19″ rack with a standard size. Such 19″ racks are available in different heights. The backplane may comprise power supply connections as well as analog and digital data connections. The backplane may e.g. comprise standard connectors that automatically connect to an inserted module, like e.g. the chamber housing, when the respective module is inserted into the rack.

The rack may also be pre-equipped with hardware, like e.g. a power supply or the like. A control unit or a computer, measuring devices, signal generators and the like may e.g. be provided as additional modules in the rack.

In a possible embodiment, the height of the portable anechoic chamber may be larger than the width of the anechoic chamber, and the width of the anechoic chamber may especially be below 105 cm.

The width of 105 cm is below the size of standard laboratory or office doors and therefore allows easily transporting/moving the portable anechoic chamber in office or laboratory buildings.

In a possible embodiment, the portable anechoic chamber may comprise lockable wheels on at least one side of an outer surface of the portable anechoic chamber.

The lockable wheels may be provided on any one of the sides of the portable anechoic chamber. Providing the lockable wheels on the lower bottom side of the portable anechoic chamber allows easily moving the portable anechoic chamber and then fixing it in place where necessary. If the lockable wheels are alternatively or in addition provided e.g. on the back side, the portable anechoic chamber may be tipped over to that side and may be moved e.g. where the height of the portable anechoic chamber would otherwise be too high.

In a possible embodiment, the portable anechoic chamber may comprise fixation elements on at least one side of an outer surface of the portable anechoic chamber.

The fixation elements may serve to hold the portable anechoic chamber in place one time it is positioned at its operating location. The fixation elements may comprise any kind of mechanical element that serves to fix the portable anechoic chamber e.g. to a wall, to a hanger assembly, mounting brackets that may be provided or the like.

With the fixation elements the portable anechoic chamber may be secured against tipping over. This is especially useful if the portable anechoic chamber is higher than it is wide.

In a possible embodiment, the fixation elements may comprise releasable clamps and/or releasable clips and/or releasable suction cups.

The releasable fixation elements may e.g. comprise levers, push buttons or the like to fix and release the respective fixation element.

A single person may therefore easily actuate the fixation elements.

In a possible embodiment, the fixation elements may comprise electrical connectors.

The connectors may e.g. automatically connect to connectors of another portable anechoic chamber or to connectors provided on a wall of the office or laboratory in which the portable anechoic chamber is deployed. It is therefore not necessary to provide separate or dedicated supply and data lines to the portable anechoic chamber.

### BRIEF DESCRIPTION OF THE DRAWINGS

For a more complete understanding of the present invention and advantages thereof, reference is now made to the following description taken in conjunction with the accompanying drawings. The invention is explained in more detail below using exemplary embodiments which are specified in the schematic figures of the drawings, in which:

FIG. 1 shows a schematic drawing of an embodiment of a portable anechoic chamber according to the present invention;

FIG. 2 shows a schematic drawing of another embodiment of a portable anechoic chamber according to the present invention;

FIG. 3 shows a schematic drawing of another embodiment of a portable anechoic chamber according to the present invention;

FIG. 4 shows a schematic drawing of another embodiment of a portable anechoic chamber according to the present invention; and

FIG. 5 shows a schematic drawing of another embodiment of a portable anechoic chamber according to the present invention.

The appended drawings are intended to provide further understanding of the embodiments of the invention. They illustrate embodiments and, in conjunction with the description, help to explain principles and concepts of the invention. Other embodiments and many of the advantages mentioned become apparent in view of the drawings. The elements in the drawings are not necessarily shown to scale.

In the drawings, like, functionally equivalent and identically operating elements, features and components are provided with like reference signs in each case, unless stated otherwise.

### DETAILED DESCRIPTION OF THE DRAWINGS

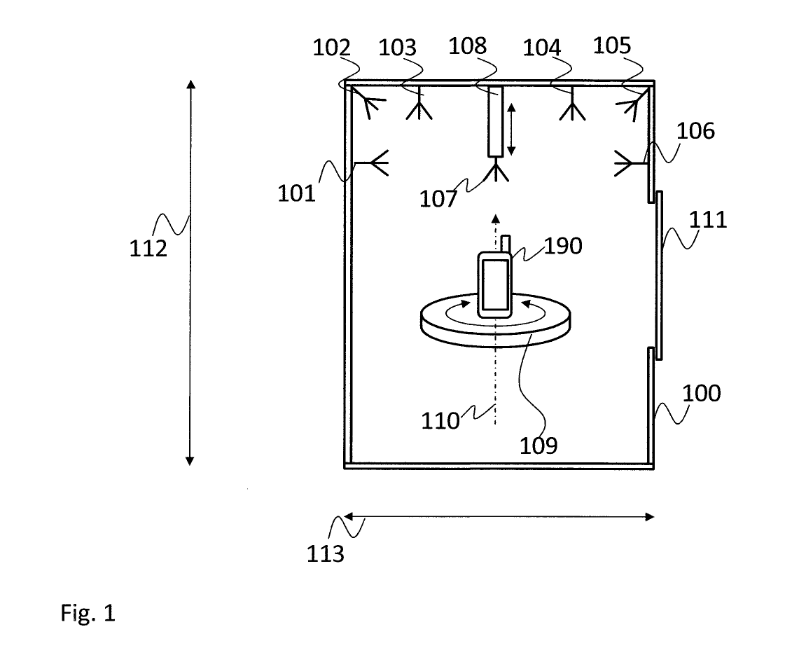

FIG. 1 shows a schematic drawing of an embodiment of a portable anechoic chamber 100 in a side view. The portable anechoic chamber 100 comprises a door 111 for accessing the inner chamber and e.g. mounting or positioned the device under test 190.

Inside of the portable anechoic chamber 100 a plurality of test antennas 101-107 are provided. The test antennas 101-106 are provided fixed on the housing of the portable anechoic chamber 100. The test antenna 107 however is provided on an antenna positioning means 108. The device under test 190 is provided on a device positioning means 109.

The antenna positioning means 108 can move the test antenna 107 up and down, i.e. in elevation direction regarding the device under test 190. This allows adjusting the distance between the test antenna 107 and the device under test 190.

The device positioning means 109 can rotate the device under test 190 around a center axis 110 and therefore position the device under test 190 in azimuth direction.

In the portable anechoic chamber 100 only one test antenna 107 is provided on the antenna positioning means 108. It is however understood that any number of test antennas may be provided on the antenna positioning means 108. Optionally, the test antennas 101-106 on the inner surface of the housing may be omitted entirely. The test antennas 101-107 may comprise either antenna elements or over the air power sensors or any combination thereof.

In FIG. 1 the height 112 and width 113 of the portable anechoic chamber 100 are marked. In one embodiment the portable anechoic chamber 100 is higher than it is wide. Further, the width 113 of the portable anechoic chamber 100 may be e.g. 105 cm or less.

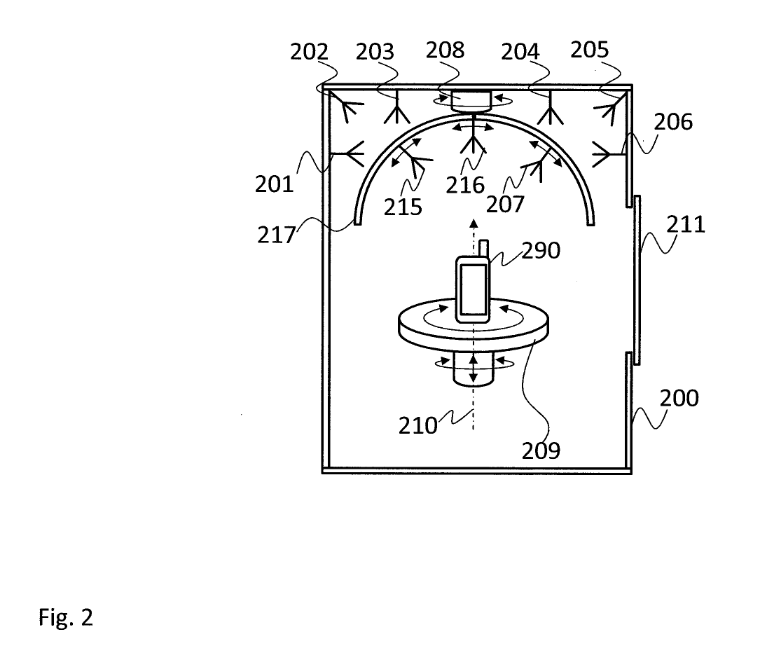

FIG. 2 shows a schematic drawing of another portable anechoic chamber 200 in a side view. The portable anechoic chamber 200 is based on the portable anechoic chamber 100. Therefore, the portable anechoic chamber 200 comprises the door 211, the device positioning means 209 with the device under test 290 and the test antennas 201-207.

However in the portable anechoic chamber 200 the antenna positioning means 208 carries an arc-shaped guide 217 that carries three test antennas 207, 215, 216. It is understood that the number of three test antennas 207, 215, 216 is just exemplarily chosen for purpose of explanation and that any other number of test antennas 207, 215, 216 may be provided on the arc-shaped guide 217.

The antenna positioning means 208 itself cannot only move the arc-shaped guide 217 up and down but also rotate the arc-shaped guide 217. The arc-shaped guide 217 allows moving the test antennas 207, 215, 216 along the arc-shaped guide 217. Any type of slides or carriages may be provided on the arc-shaped guide 217 that allow moving the test antennas 207, 215, 216 along the arc-shaped guide 217.

It can be seen that by moving the test antennas 207, 215, 216 on the arc-shaped guide 217 the test antennas 207, 215, 216 are also tilted such that they always point in the direction of the device under test 290.

Further, the single test antennas 207, 215, 216 may be fixed to the arc-shaped guide 217 with pivotable hinges that allow rotating the test antennas 207, 215, 216 about their main axis to adjust the polarizations of the test antennas 207, 215, 216 with respect to the device under test 290.

Further, the device positioning means 209 of the portable anechoic chamber 200 not only allows rotating the device under test 290 but also allows moving the device under test 290 up and down.

Although not explicitly shown, it is understood that the arc-shaped guide 217 may in another embodiment also comprise a straight guide or a single gantry arm or robot arm with a plurality of joints. On such a gantry arm or robot arm a single test antenna may be positioned or a plurality of test antennas may be positioned. The gantry arm or robot arm may e.g. carry the arc-shaped guide 217 with the test antennas 207, 215, 216.

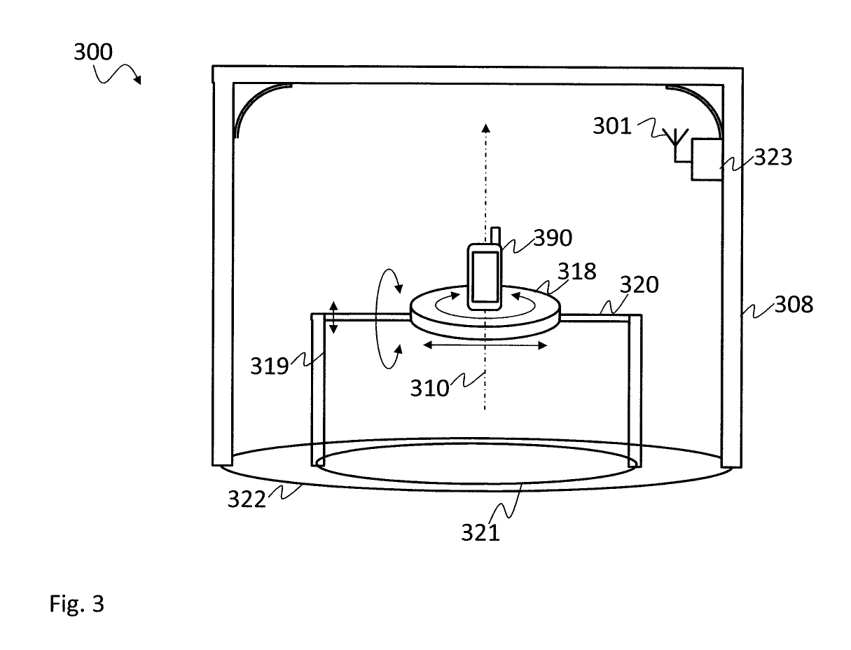

FIG. 3 shows a schematic drawing of another portable anechoic chamber 300, wherein only the inner details of the portable anechoic chamber 300 are shown in detail. The portable anechoic chamber 300 provides the same degrees of freedom as the portable anechoic chamber 100 and the portable anechoic chamber 200 but with different mechanical constructions.

The portable anechoic chamber 300 comprises an outer gantry arrangement 308 and an inner gantry arrangement (not separately referenced). The gantry arrangements are both provided on circular guides 322, 321 or rails, which allow turning the outer gantry arrangement 308 and the inner gantry arrangement around the vertical axis 310.

A test antenna 301 is provided on a slide 323 for moving the test antenna 301 or the outer gantry arrangement 308. The inner gantry arrangement is formed by two gantry stands 319 connected by a gantry center support 320 that carries the rotation plate 318 with the device under test 390. The gantry center support 320 can move up and down along the gantry stands 319 to move the device under test 390 vertically. Further, the rotation plate 318 may move horizontally on the gantry center support 320. Optionally the rotation plate 318 may be pivotable around the gantry center support 320.

Although not shown in detail, the outer gantry arrangement 308 and the inner gantry arrangement may comprise any type of rails or guides and slides 323 for moving the test antenna 301 and the device under test 390. The brackets in the corners of the outer gantry arrangement 308 indicate that the slide 323 may freely move on the circumference of the outer gantry arrangement 308. As alternative single side gantry arrangements, like e.g. robot arms with a plurality of joints or hinges may be provided.

It is understood that the features of the portable anechoic chamber 100, and the portable anechoic chamber 200 may be mixed with the features of the portable anechoic chamber 300. An exemplary test arrangement may e.g. comprise the outer gantry arrangement 308 and the device positioning means 109, 209. Another exemplary test arrangement may also comprise the inner gantry arrangement with the antenna positioning means 108, 208 and optionally the arc-shaped guide 217.

Although not explicitly shown it is clear that every moving element of the embodiments of the portable anechoic chamber disclosed herein may comprise manual or electric drives to position the respective element. Electric drives may e.g. be controlled by a test controller based on a test schedule or the like.

Further, it is understood that any required cables and connections to the test antennas and the device under test may be provided as necessary. Such cables may comprise rotary joints and/or slip rings as necessary for providing the required degrees of freedom for moving the test antennas or the device under test.

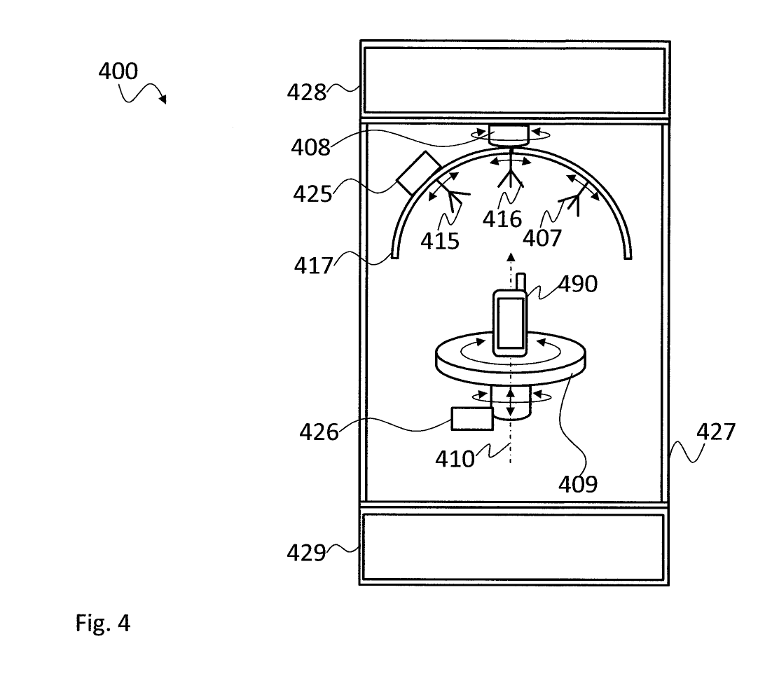

FIG. 4 shows a schematic drawing of another portable anechoic chamber 400 in a front view. The portable anechoic chamber 400 is based on the portable anechoic chamber 200. However, the test antennas 201-206 have been omitted and the antenna positioning means 408 carries the only test antennas 407, 415, 416. Again, the number of test antennas 407, 415, 416 is just exemplarily chosen.

In the portable anechoic chamber 400 a signal processing means 425 is provided on the arc-shaped guide 417. Another signal processing means 426 is provided on the device positioning means 409. It is understood, that the signal processing means 425 can be connected by any type of cables or busbars to the test antennas 407, 415, 416. The same applies to the signal processing means 426 and the device under test 490.

The portable anechoic chamber 400 comprises a chamber housing 427. The chamber housing 427 comprises the test installation as e.g. explained with regard to FIGS. 1-3. However, in addition to the chamber housing 427 an upper compartment 428 and a lower compartment 429 are shown. It is understood that the dimensions are just exemplarily chosen and are not necessary to scale. It is understood that the relative sizes, especially the heights, of the chamber housing 427, the upper compartment 428 and the lower compartment 429 may vary.

The upper compartment 428 and the lower compartment 429 may e.g. serve to accommodate test equipment and test control devices. Such equipment and devices may be coupled to the test antennas 407, 415, 416, the device under test 490, the signal processing means 425 and the signal processing means 426 e.g. via cables, busbars or backplanes that may be integrated into the structure of the portable anechoic chamber 400.

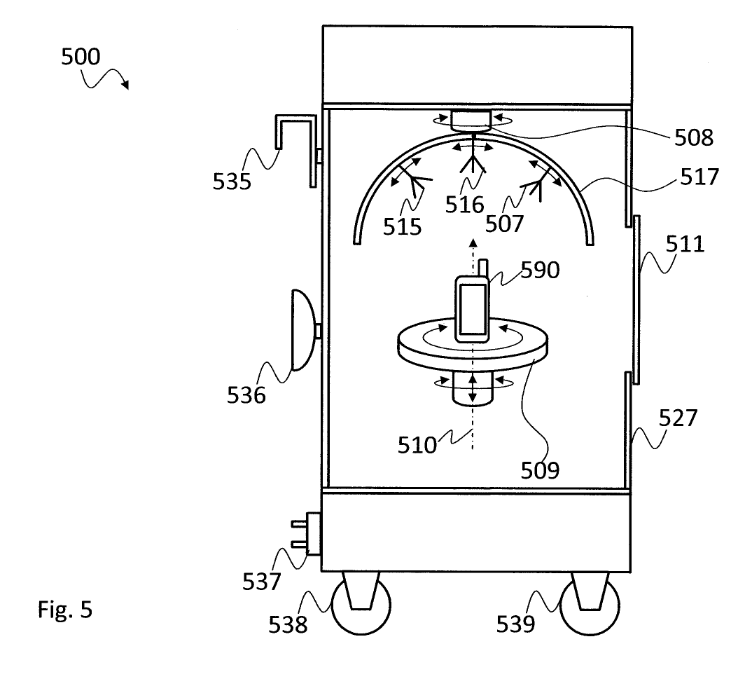

FIG. 5 shows a schematic drawing of another embodiment of a portable anechoic chamber 500 in a side view. The portable anechoic chamber 500 is based on the portable anechoic chamber 400 and comprises additional mechanical elements for fixating the portable anechoic chamber 500. The signal processing means 425 and the signal processing means 426 have been omitted.

The portable anechoic chamber 500 for example comprises a hook 535 and a suction cup 536. The hook 535 and the suction cup 536 are exemplarily provided on the back of the portable anechoic chamber 500. It is understood that the hook 535 and the suction cup 536 may also be provided on any other side of the portable anechoic chamber 500 as required.

The hook 535 may e.g. interlock with a counterpart that may e.g. be provided on a wall of a laboratory or office. The suction cup 536 may be used to fix the portable anechoic chamber 500 to any smooth surface. It is understood that manual actuation of the hook 535 and the suction cup 536 may be provided. In addition an automatic actuation of the hook 535 and the suction cup 536 may be provided that automatically fixes the portable anechoic chamber 500 to the respective counterpart when it is detected in the correct position.

The portable anechoic chamber 500 further comprises a connector 537. The connector 537 is just schematically shown and can be provided as any type of connector 537. The connector 537 may e.g. automatically engage with a counterpart when the hook 535 or the suction cup 536 engages with its respective counterpart.

The connector 537 may provide power supply and digital data connections as well as analog signal lines, as required. The connector 537 or additional connectors may also be provided e.g. on a side of the portable anechoic chamber 500. Such a side-connector may serve to couple the portable anechoic chamber 500 to other portable anechoic chambers 500.

The portable anechoic chamber 500 further comprises lockable wheels 538, 539 on the bottom side. The lockable wheels 538, 539 provide for an easy movement of the portable anechoic chamber 500 and at the same time allow safely fixing the portable anechoic chamber 500 in position by applying the brakes or locks of the lockable wheels 538, 539.

Although specific embodiments have been illustrated and described herein, it will be appreciated by those of ordinary skill in the art that a variety of alternate and/or equivalent implementations exist. It should be appreciated that the exemplary embodiment or exemplary embodiments are only examples, and are not intended to limit the scope, applicability, or configuration in any way. Rather, the foregoing summary and detailed description will provide those skilled in the art with a convenient road map for implementing at least one exemplary embodiment, it being understood that various changes may be made in the function and arrangement of elements described in an exemplary embodiment without departing from the scope as set forth in the appended claims and their legal equivalents. Generally, this application is intended to cover any adaptations or variations of the specific embodiments discussed herein.

In the foregoing detailed description, various features are grouped together in one or more examples or examples for the purpose of streamlining the disclosure. It is understood that the above description is intended to be illustrative, and not restrictive. It is intended to cover all alternatives, modifications and equivalents as may be included within the scope of the invention. Many other examples will be apparent to one skilled in the art upon reviewing the above specification.

Specific nomenclature used in the foregoing specification is used to provide a thorough understanding of the invention. However, it will be apparent to one skilled in the art in light of the specification provided herein that the specific details are not required in order to practice the invention. Thus, the foregoing descriptions of specific embodiments of the present invention are presented for purposes of illustration and description. They are not intended to be exhaustive or to limit the invention to the precise forms disclosed; obviously many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated. Throughout the specification, the terms “including” and “in which” are used as the plain-English equivalents of the respective terms “comprising” and “wherein,” respectively. Moreover, the terms “first,” “second,” and “third,” etc., are used merely as labels, and are not intended to impose numerical requirements on or to establish a certain ranking of importance of their objects.

### LIST OF REFERENCE SIGNS

100, 200, 300, 400, 500 portable anechoic chamber

101-107, 201-207 test antennas

215, 216, 301 test antennas

407, 415, 416, 507, 515, 516 test antennas

108, 208, 308, 408, 508 antenna positioning means

109, 209, 409, 509 device positioning means

110, 210, 310, 410, 510 axis

111, 211, 511 door

112 height

113 width

217, 417, 517 arc-shaped guide

318 rotation plate

319 gantry stand

320 gantry center support

321, 322 guide

323 slide

425, 426 signal processing means

427 chamber housing

428, 429 compartment

535 hook

536 suction cup

537 connector

538, 539 lockable wheel

190, 290, 390, 490, 590 device under test

1. A portable anechoic chamber for testing a device under test, the portable anechoic chamber comprising:
a number of test antennas, each test antenna having at least one polarization,
an antenna positioning means for positioning at least one of the test antennas in elevation direction relative to the device under test,
a device positioning means for positioning the device under test in azimuth direction.

2. The portable anechoic chamber according to claim 1, wherein the antenna positioning means comprises a linear positioning unit for positioning the at least one test antenna in a direction orthogonal to the elevation movement.

3. The portable anechoic chamber according to claim 2, wherein the linear positioning unit moves the at least one test antenna on an arc-shaped path.

4. The portable anechoic chamber according to claim 3, wherein the linear positioning unit rotates the at least one test antenna such that the at least one test antenna points to the device under test on all points of the arc-shaped path.

5. The portable anechoic chamber according to claim 1, wherein the antenna positioning means comprises a rotational positioning unit for rotating the at least one test antenna in an axis parallel to the elevation movement.

6. The portable anechoic chamber according to claim 1, wherein the antenna positioning means comprises for every single test antenna a rotatable joint for rotating the test antennas about the axis of main sensitivity of the respective test antenna.

7. The portable anechoic chamber according to claim 1, wherein the antenna positioning means and/or the device positioning means comprise electric positioning drives for positioning the test antennas and/or the device under test, respectively.

8. The portable anechoic chamber according to claim 1, wherein the device positioning means comprises a rotatable support for the device under test for rotating the device under test about a vertical axis.

9. The portable anechoic chamber according to claim 8, wherein the rotatable support comprises a pivotable joint for pivoting the device under test out of the rotating axis.

10. The portable anechoic chamber according to claim 1, wherein the antenna positioning means and/or the device positioning means comprise a gantry arrangement.

11. The portable anechoic chamber according to claim 1, wherein the antenna positioning means comprises signal processing means connected to the test antennas.

12. The portable anechoic chamber according to claim 1, wherein the device positioning means comprises signal processing means connected to the device under test.

13. The portable anechoic chamber according to claim 1, wherein at least one of the test antennas comprises an over the air power sensor.

14. The portable anechoic chamber according to claim 1, comprising cables connecting the test antennas and/or the device under test, wherein the cables comprise rotary joints and/or slip rings.

15. The portable anechoic chamber according to claim 1, comprising a chamber housing that at least comprises the antenna positioning means with the test antennas, and the device positioning means, the portable anechoic chamber further comprising a lower device compartment arranged under the chamber housing and/or an upper device compartment arranged above the chamber housing.

16. The portable anechoic chamber according to claim 15, comprising a control unit in the lower device compartment and/or the upper device compartment.

17. The portable anechoic chamber according to claim 15, comprising a rack with an electric backplane, wherein the chamber housing is installed in the rack and communicated via the backplane.

18. The portable anechoic chamber according to claim 1, wherein the height of the portable anechoic chamber is larger than the width of the anechoic chamber, and/or wherein the width of the anechoic chamber is below 105 cm.

19. The portable anechoic chamber according to claim 1, comprising lockable wheels on at least one side of an outer surface of the portable anechoic chamber.

20. The portable anechoic chamber according to claim 1, comprising fixation elements on at least one side of an outer surface of the portable anechoic chamber.

21. The portable anechoic chamber according to claim 20, wherein the fixation elements comprise releasable clamps and/or releasable clips and/or releasable suction cups.

22. The portable anechoic chamber according to claim 20, wherein the fixation elements comprise electrical connectors.
